(19) United States
(12) Patent Application Publication
(10) Pub. No.: US 2026/0196280 A1
(43) Pub. Date: Jul. 9, 2026

(54) SELECTIVE BLOCK RETIREMENT FOR A MEMORY DEVICE

(71) Applicant: Micron Technology, Inc., Boise, ID (US)

(72) Inventors: Daniel Danching Zhang, Milpitas, CA (US); Tingjun Xie, Milpitas, CA (US); David Scott Ebsen, Minnetonka, MN (US); John Kane, Westminster, CO (US); Sead Zildzic, Folsom, CA (US)

(21) Appl. No.: 19/012,629

(22) Filed: Jan. 7, 2025

(51) Int. Cl. G11C 16/34; G11C 16/10

(52) U.S. Cl. CPC G11C 16/349; G11C 16/102; G11C 16/3418

(57) ABSTRACT

A system comprises a memory device and a processing device, the processing device operatively coupled with the memory device to perform operations. Responsive to determining a block satisfies a checking pool threshold criterion, the processing device assigns the block to from an active pool to a checking pool. The processing device performs a reliability checking (RC) scan on the block. The processing device determines, based on a reliability metric associated with the block and determined from the RC scan, whether the block satisfies a retirement threshold criterion. Responsive to determining that the block satisfies the retirement threshold criterion, the processing device retires at least a portion of the block, wherein memory operations can no longer be performed on the retired portion of the block.

### TECHNICAL FIELD

Embodiments of the disclosure relate generally to memory sub-systems, and more specifically, relate to a system and method of selective block retirement in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 is a flow diagram of an example method to manage and selectively retire blocks in a memory device, in accordance with some embodiments of the present disclosure.

FIG. 3 is an example block diagram illustrating the various states a memory block can undergo during its lifecycle, in accordance with some embodiments of the present disclosure.

FIG. 4 is a block diagram of an example computer system in which embodiments of the present disclosure may operate.

### DETAILED DESCRIPTION

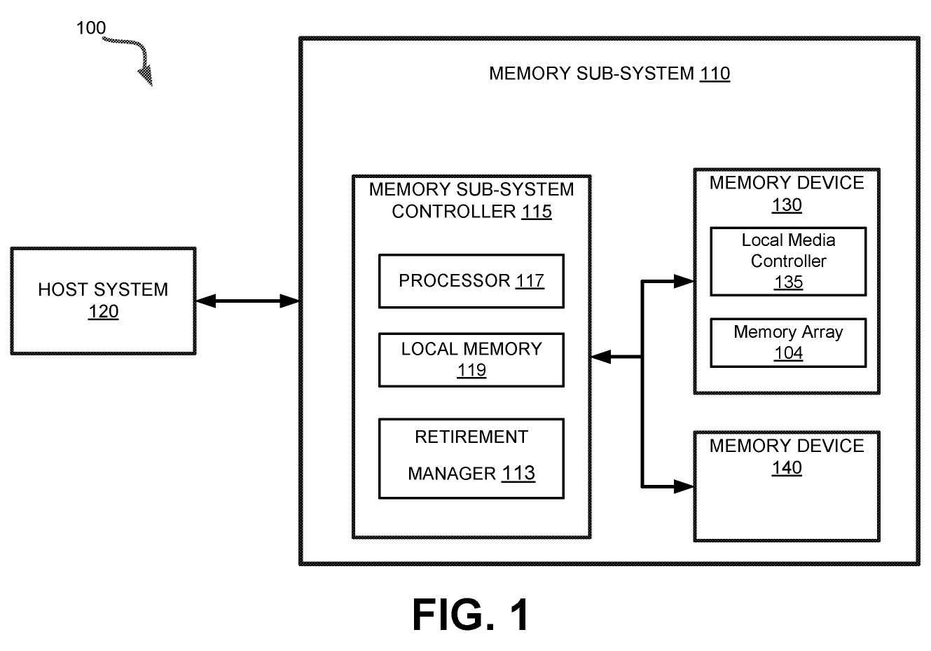

Aspects of the present disclosure are directed to a system and method of selective block retirement for a memory device. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can include one or more planes. For some types of non-volatile memory devices (e.g., NAND devices), each plane includes of a set of physical blocks. Each block includes of a set of pages. Each page includes of a set of memory cells ("cells"). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

The endurance of memory devices (e.g., the longevity linked to the ability of the memory device to maintain reliability and performance standards), is often limited by their intrinsic reliability capabilities. For example, a memory device is susceptible to slow charge loss (SCL). SCL refers to the gradual degradation of the electric charge stored in memory cells, causing a temporal voltage shift (TVS)—a change in the cell's threshold voltage as a function of time. This shift can lead to increased bit error rates during read operations.

Memory devices are also susceptible to latent read disturb. Latent read disturb is where repeated read operations progressively degrade nearby memory cells, diminishing their data retention capabilities. With increased usage cycles, memory devices become more prone to read disturb, potentially leading to data loss. Issues like slow charge loss (SCL) and latent read disturb progressively degrade a memory device’s data retention capabilities, affecting reliability.

Some conventional approaches address these reliability challenges by applying settings that cater to worst-case or suboptimal scenarios, often necessitating performance compromises for a minority percentage of the device population. Other conventional approaches focus on adjusting system settings as a function of the cycle count—for instance, modifying trims after every 500 read cycles. However, this generally only addresses typical-case scenarios and fails to adequately mitigate the variability and outliers associated with worst-case reliability issues.

Furthermore, initial manufacturing processes involve specialized screening and stress testing to identify marginalities in materials before deployment. However, these tests are conducted at the beginning of life (BOL) and often fail to account for reliability degradation or intrinsic defects that manifest at end of life (EOL). In addition, conventional application of stress tests are time-consuming with potential latency impacts. As such, many systems apply minimal stress testing, resulting in a lack of proactive measures to address degradation, leaving systems vulnerable to reliability issues as they approach the end of their lifecycle.

Consequently, current solutions are insufficient for maintaining performance while ensuring reliability, particularly as memory devices must implement significant margins to accommodate worst-case scenarios.

Aspects of the present disclosure address the above and other deficiencies by having a memory sub-system that manages and selectively retires blocks for a memory device. In essence, the system is retiring blocks exhibiting poor reliability and which may affect the overall reliability of the memory device. When the system detects that a block of memory meets certain conditions, it assigns the block to a "checking pool" for further evaluation. This checking pool serves as a focused area where the system monitors blocks that may need closer attention. Blocks that need closer attention can include blocks exceeding a certain number of read or write cycles or blocks with too much invalid data.

Once the block is assigned to the checking pool (e.g., in a checking state), the system performs a reliability checking (RC) scan on the block. This RC scan gathers data about the block's reliability, helping to determine whether it meets the necessary performance and stability standards. In some embodiments, the RC scan involves erasing the block and programming a data pattern to the block. A data pattern can be utilized to execute a test case, with specific trims configured to introduce stresses targeted by the test objectives. Furthermore, depending on the test objectives, the RC scan can involve multiple measurements. For example, in checking for SCL, the system can take multiple measurements at predetermined or dynamic time intervals to measure the rate of charge loss over time. The result of the RC scan is a reliability metric, such as a raw bit error rate (RBER). The reliability metric is compared against a retirement threshold criterion indicating the riskiness of the block. If the block does not meet the required reliability standards, it is retired, meaning that it is no longer used for memory operations. If the block does meet the required reliability standards (i.e., it fails to satisfy the retirement threshold criterion), the block is deemed acceptable and can continue to be used for memory operations.

Advantages of the present disclosure include, but are not limited to enhanced memory device reliability, performance, and endurance. By selectively retiring memory blocks that exhibit reliability outliers, the system eliminates the need to accommodate the weakest links. This approach enables the memory device to operate at higher performance levels with greater overall reliability. The present disclosure also improves the endurance of the memory device as it allows the device to meet the necessary reliability and performance requirements for longer. Furthermore, by selectively checking only blocks that are a reliability risk, the present disclosure avoids the introducing the latency impact of conventional stress testing methods.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a retirement manager component 113 that can selectively retire blocks in a memory device. In some embodiments, the memory sub-system controller 115 includes at least a portion of the retirement manager component 113. In some embodiments, the retirement manager component 113 is part of the host system 120, an application, or an operating system. In other embodiments, local media controller 135 includes at least a portion of retirement manager component 113 and is configured to perform the functionality described herein.

The retirement manager component 113 can manage and selectively retire blocks of a memory device. When the system detects that a block of memory meets certain conditions, it assigns the block to a "checking pool" for further evaluation. This checking pool serves as a focused area where the system monitors blocks that may need closer attention. Blocks that need closer attention can include blocks exceeding a certain number of read or write cycles or blocks with too much invalid data.

Once the block is assigned to the checking pool (e.g., in a checking state), the system performs a reliability checking (RC) scan on the block. This RC scan gathers data about the block's reliability, helping to determine whether it meets the necessary performance and stability standards. In some embodiments, the RC scan involves erasing the block and programming a data pattern to the block. A data pattern can be utilized to execute a test case, with specific trims configured to introduce stresses targeted by the test objectives. Furthermore, depending on the test objectives, the RC scan can involve multiple measurements. For example, in checking for SCL, the system can take multiple measurements at predetermined or dynamic time intervals to measure the rate of charge loss over time. The result of the RC scan is a reliability metric, such as a raw bit error rate (RBER). The reliability metric is compared against a retirement threshold criterion indicating the riskiness of the block. If the block does not meet the required reliability standards, it is retired, meaning that it is no longer used for memory operations. If the block does meet the required reliability standards (i.e., it fails to satisfy the retirement threshold criterion), the block is deemed acceptable and can continue to be used for memory operations. Further details with regards to the operations of the retirement manager component 113 are described below.

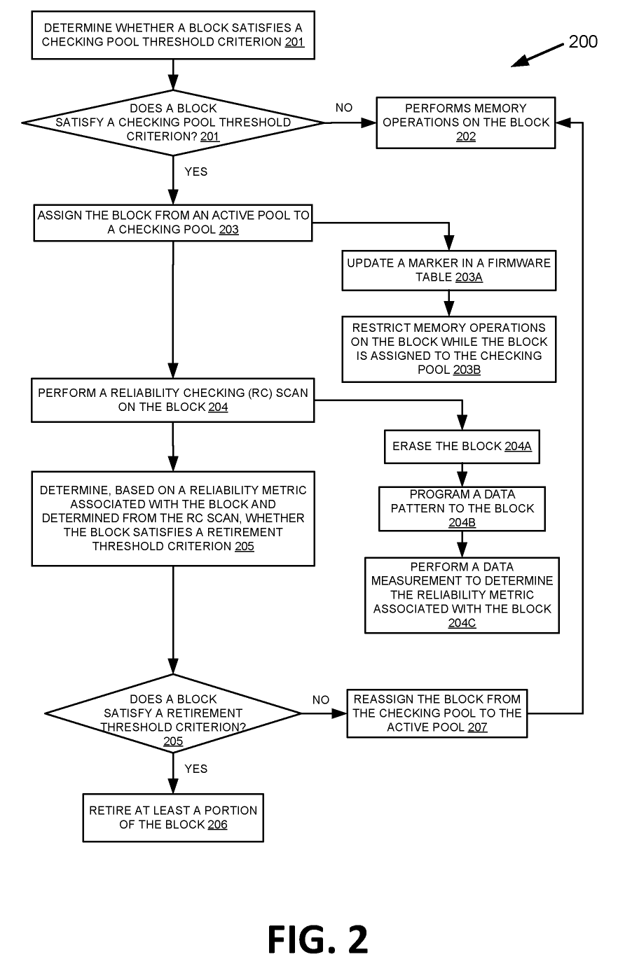

FIG. 2 is a flow diagram of an example method 200 to manage and selectively retire blocks in a memory device, in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the retirement manager component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

In certain embodiments, the processing logic manages units of memory beyond blocks. For example, these embodiments manage (and selectively retire) larger or more granular units such as planes, dies, or pages.

At operation 201, the processing logic (e.g., retirement manager component 113) determines whether a block satisfies a checking pool threshold criterion. In some embodiments, the checking pool corresponds with a state (e.g., a checking state) the block undergoes.

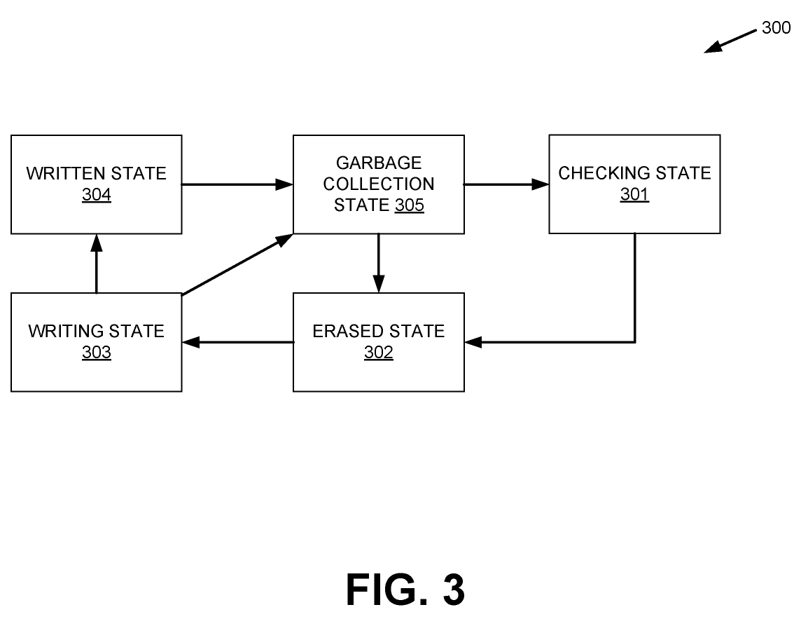

FIG. 3 is an example block diagram 300 illustrating the various states a memory block can undergo during its lifecycle, in accordance with some embodiments of the present disclosure. The states include a checking state 301, and erased state 302, a writing state 303, a written state 304, and a garbage collection state 305. Although shown in a particular sequence or order, unless otherwise specified, the order of the states can be modified. Thus, the illustrated embodiments should be understood only as examples, and the illustrated states can be entered in a different order. Additionally, one or more states can be omitted in various embodiments. Thus, not all states are required in every embodiment. Other state flows are possible.

In the erased state 302, the block is cleared of all data, making it ready to store new information. This state ensures that no residual data interferes with subsequent operations. The writing state 303 represents the process of writing data to the block. During this state, data is programmed into the block. In some embodiments, the block is in the writing state 303 until it is completely written to. After the block has been successfully written to, the block transitions to the written state 304, storing the written data until it is either read, modified, or marked for garbage collection.

The garbage collection (GC) state 305 is initiated when a memory block is designated for cleanup. In some embodiments, during this state, invalid or obsolete data within the block is discarded, and valid data, if present, is relocated to other memory locations. Once the block is cleared of all unnecessary data, it is erased and prepared for reuse in the erased state 302. In some embodiments, GC occurs as a background operation to minimize impact on system performance. In some embodiments, GC operations are triggered during active operations when the available free space in the memory device drops below a critical threshold.

Referring to FIG. 2, in some embodiments, upon the block entering the GC state 305, the processing logic determines whether a block satisfies a checking pool threshold criterion (e.g., operation 201). Other embodiments can implement where the block can enter the checking state 301 from other states (e.g., erased state 302, writing state 303, written state 304, etc.).

The checking pool threshold criterion can vary depending on the embodiment. Examples include, but are not limited to, thresholds based on the percentage of invalid data within a block, the maximum allowable number of memory operation cycles (i.e., read or write cycles) performed on a block, or other metrics specific to the system’s reliability and performance requirements.

For example, in some embodiments, the checking pool threshold criterion is a maximum allowable invalidity percentage. The invalidity percentage is the percentage of the total data stored in the block that is invalid. In some embodiments, a block satisfies the checking pool threshold criterion when a percentage of data in the block that is invalid is greater than a maximum allowable invalidity percentage. Therefore, if the percentage of data in the block that is invalid is less than or equal to the maximum allowable invalidity percentage, the block fails to satisfy the checking pool threshold criterion and the block is not assigned to the checking pool. In an alternative example, in some embodiments, the checking pool threshold criterion is a maximum allowable number of memory operation cycles performed on a block. For example, a block can satisfy the checking pool threshold criterion when the total number of read cycles performed on the block reaches a predefined maximum limit.

Responsive to the block failing to satisfy the checking pool threshold criterion, at operation 202, the processing logic performs memory operations on the block. In some embodiments, the memory operations performed on the block utilize host data stored on the block or host data that is to be stored on the block.

Responsive to determining the block satisfies the checking pool threshold criterion, at operation 203, the processing logic assigns the block from an active pool to a checking pool (e.g., the block enters a checking state 301). In some embodiments, in assigning the block to the checking pool, at operation 203A, the processing logic updates a marker in a firmware table. The marker can indicate whether a block meets the criteria for further evaluation such as stress testing, serving as a status indicator for the block (e.g., whether the block qualifies for the checking pool). In some embodiments, the firmware table is structured as an indexed list, with each entry corresponding to a specific block in the memory device. In some embodiments, the entry includes fields such as a block identifier and a marker. In some embodiments, the firmware table is stored in a non-volatile memory device (e.g., memory device 130 of FIG. 1).

In some embodiments, in assigning the block to the checking pool, at operation 203B, the processing logic restricts the memory operations performed on the block while the block is assigned to the checking pool (and in the checking state 301). In some embodiments, the restriction entails that the block is restricted from memory operations using host data. For example, the block is not being used to store host data. Conversely, in some embodiments, blocks in the active pool are designated for storing host data and are maintained in states that allow memory operations involving host data (e.g., the erased state 302, the writing state 303, the written state 304, the garbage collection state 305, etc.). For example, memory operations performed on a block assigned to the active pool involve utilizing host data stored on the block or preparing host data that is to be written to the block (e.g., the memory operations are not restricted).

At operation 204, the processing logic performs a reliability checking (RC) scan on the block. In some embodiments, performing the RC scan on the block comprises, at operation 204A, erasing the block. At operation 204B, the processing logic programs a data pattern to the block. The RC scan is a controlled testing procedure used to evaluate specific failure mechanisms and reliability metrics under defined conditions.

A data pattern is a specific sequence of bits written to a block during testing to identify faults and assess reliability. In some embodiments, the data pattern is programmed using predetermined trim settings. As part of the data pattern, trims can be adjusted to stress memory cell characteristics under specified voltage, temperature, and timing conditions.

At operation 204C, the processing logic performs a data measurement to determine the reliability metric associated with the block. In some embodiments, the reliability metric comprises a raw bit error rate (RBER). The RBER corresponds to the number of bit errors per unit of time that the data stored at the block experiences. Different embodiments can use various reliability metrics tailored to specific reliability goals. For example, one design might emphasize data retention indicators such as RBER. Different embodiments can use various testing strategies depending on the focus of the test.

For example, in some embodiments, SCL is assessed by verifying data retention after extended dwell times. In some embodiments, the data measurement is performed at predetermined time intervals to track changes in charge systematically. In some embodiments, the data measurement is performed at dynamic time intervals, wherein the dynamic time intervals are set as a function of temperature. For example, at higher temperatures where blocks can be more susceptible to SCL, the time intervals between data measurements are shorter. In some embodiments, the processing logic can adjust testing parameters (e.g., data pattern, trim settings, etc.) at the time intervals.

In an alternative example where the RC scan is designed to evaluate the latent rad disturb of a block, in some embodiments, the processing logic introduces stress by subjecting the block to a predetermined number of read operations, such as performing 1,000 consecutive reads. After applying this stress, the processing logic performs a data measurement to detect errors such as bit flips or data corruption and assess the integrity of adjacent memory cells and the data retention capabilities of the block.

At operation 205, the processing logic determines, based on a reliability metric associated with the block and determined from the RC scan, whether the block satisfies a retirement threshold criterion.

In some embodiments, the retirement threshold criterion is a maximum allowable reliability metric. In some embodiments, a block satisfies the retirement threshold criterion when the reliability metric is greater than a maximum allowable reliability metric. Therefore, in some embodiments, a block fails to satisfy the retirement threshold criterion when the reliability metric is less than or equal to the maximum allowable reliability metric. For example, if an RBER (e.g., the reliability metric) associated with the block determined from the RC scan is greater than a predetermined maximum allowable RBER (e.g., the maximum allowable reliability metric), the block satisfies the retirement threshold criterion.

In some embodiments, at operation 206, responsive to determining that the block satisfies the retirement threshold criterion, the processing logic retires at least a portion of the block. In some embodiments, the retired portion comprises individual pages. In some embodiments, the retired portion comprises the entire unit of memory (e.g., block). In embodiments managing the memory at a granularity beyond a block (e.g., planes or dies), the retired portion comprises multiple blocks. In some embodiments, the processing logic restricts memory operations from being performed on the retired portion of the block. In some embodiments, retiring the portion of the block comprises updating a marker in a firmware table.

In some embodiments, at operation 207, responsive to determining that the block fails to satisfy the retirement threshold criterion, the processing logic reassigns the block from the checking pool to the active pool. In some embodiments, in reassigning the block to the active pool from the checking pool, the block transitions out of the checking state 301 into a state in which the block hosts memory operations with host data (e.g., the erased state 302, the writing state 303, the written state 304, the garbage collection state 305, etc.), as illustrated in FIG. 3. in some embodiments, blocks in the active pool are designated for storing host data and are maintained in states that allow memory operations involving host data (e.g., the erased state 302, the writing state 303, the written state 304, the garbage collection state 305, etc.). For example, memory operations performed on a block assigned to the active pool involve utilizing host data stored on the block or preparing host data that is to be written to the block (e.g., the memory operations are not restricted).

In some embodiments, the block is subsequently erased, entering the erased state 302 (illustrated in FIG. 3). In some embodiments, reassigning the block from the checking pool to the active pool comprises updating a marker in a firmware table. In some embodiments, responsive to reassigning the block from the checking pool to the active pool (at operation 207), the processing logic performs memory operations on the block (at operation 202), wherein the memory operations are performed using host data.

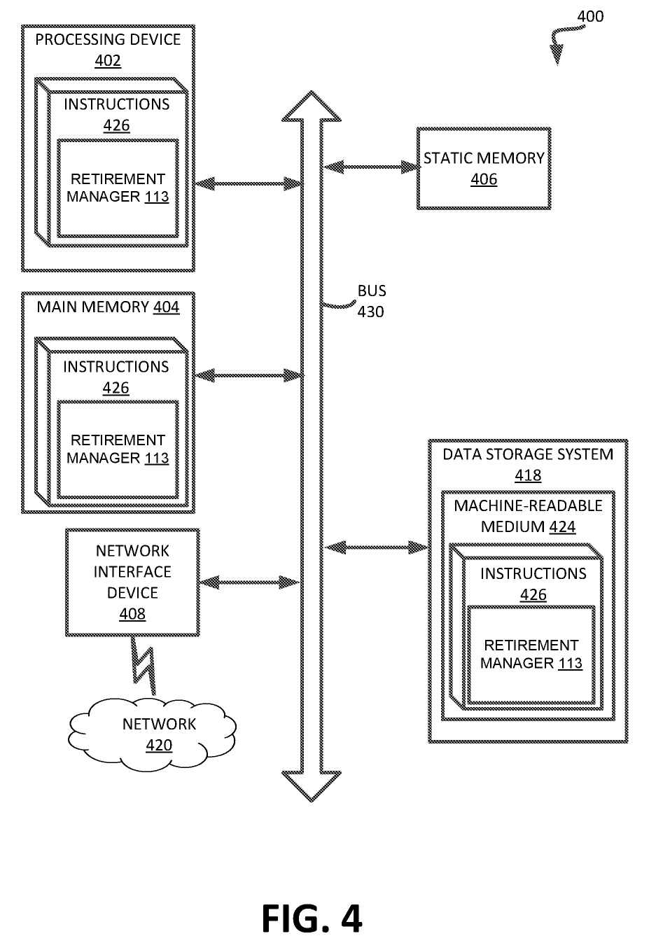

FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the retirement manager component 113 of FIG. 1). In alternative embodiments, the machine can be connected (e.g., networked) to other machines in a LAN, an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or RDRAM, etc.), a static memory 406 (e.g., flash memory, static random access memory (SRAM), etc.), and a data storage system 418, which communicate with each other via a bus 430.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to a retirement manager component (e.g., the retirement manager component 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system, comprising:
a memory device; and
a processing device, operatively coupled with the memory device, to perform operations comprising:
responsive to determining a block of the memory device satisfies a checking pool threshold criterion, assigning the block from an active pool to a checking pool;
performing a reliability checking (RC) scan on the block;
determining, based on a reliability metric associated with the block and determined from the RC scan, whether the block satisfies a retirement threshold criterion; and
responsive to determining that the block satisfies the retirement threshold criterion, retiring at least a portion of the block, wherein memory operations can no longer be performed on the retired portion of the block.

2. The system of claim 1, wherein assigning the block to the checking pool comprises updating a marker in a firmware table.

3. The system of claim 1, wherein assigning the block to the checking pool comprises restricting the memory operations on the block while the block is assigned to the checking pool.

4. The system of claim 1, wherein the block satisfies the checking pool threshold criterion when a percentage of data in the block that is invalid is greater than a maximum allowable invalidity percentage.

5. The system of claim 1, wherein performing the RC scan on the block comprises:
erasing the block;
programming a data pattern to the block; and
performing a data measurement to determine the reliability metric associated with the block.

6. The system of claim 5, wherein the data pattern is programmed using predetermined trim settings.

7. The system of claim 5, wherein the data measurement is performed at set time intervals.

8. The system of claim 5, wherein the data measurement is performed at dynamic time intervals, wherein the dynamic time intervals are set as a function of temperature.

9. The system of claim 1, wherein the reliability metric comprises a raw bit error rate (RBER), and wherein the block satisfies the retirement threshold criterion when the reliability metric is greater than a maximum allowable reliability metric.

10. The system of claim 1, responsive to determining that the block fails to satisfy the retirement threshold criterion, reassigning the block from the checking pool to the active pool.

11. A method comprising:
responsive to determining, by a processing device, a block satisfies a checking pool threshold criterion, assigning the block from an active pool to a checking pool;
performing a reliability checking (RC) scan on the block;
determining, based on a reliability metric associated with the block and determined from the RC scan, whether the block satisfies a retirement threshold criterion; and
responsive to determining that the block satisfies the retirement threshold criterion, retiring at least a portion of the block, wherein memory operations can no longer be performed on the retired portion of the block.

12. The method of claim 11, wherein assigning the block to the checking pool comprises restricting the memory operations on the block while the block is assigned to the checking pool.

13. The method of claim 11, wherein the block satisfies the checking pool threshold criterion when a percentage of data in the block that is invalid is greater than a maximum allowable invalidity percentage.

14. The method of claim 11, wherein performing the RC scan on the block comprises:
erasing the block; and
programming a data pattern to the block; and
performing a data measurement to determine the reliability metric associated with the block.

15. The method of claim 11, wherein the reliability metric comprises a raw bit error rate (RBER), and wherein the block satisfies the retirement threshold criterion when the reliability metric is greater than a maximum allowable reliability metric.

16. The method of claim 11, responsive to determining that the block fails to satisfy the retirement threshold criterion, reassigning the block from the checking pool to the active pool.

17. A non-transitory computer-readable storage medium comprising instructions that, when executed by a processing device, cause the processing device to perform operations comprising:
responsive to determining, by a processing device, a block satisfies a checking pool threshold criterion, assigning the block from an active pool to a checking pool;
performing a reliability checking (RC) scan on the block;
determining, based on a reliability metric associated with the block and determined from the RC scan, whether the block satisfies a retirement threshold criterion; and
responsive to determining that the block satisfies the retirement threshold criterion, retiring at least a portion of the block, wherein memory operations can no longer be performed on the retired portion of the block.

18. The non-transitory computer-readable storage medium of claim 17, wherein the block satisfies the checking pool threshold criterion when a percentage of data in the block that is invalid is greater than a maximum allowable invalidity percentage.

19. The non-transitory computer-readable storage medium of claim 17, wherein performing the RC scan on the block comprises:
erasing the block; and
programming a data pattern to the block; and
performing a data measurement to determine the reliability metric associated with the block.

20. The non-transitory computer-readable storage medium of claim 17, wherein the reliability metric comprises a raw bit error rate (RBER), and wherein the block satisfies the retirement threshold criterion when the reliability metric is greater than a maximum allowable reliability metric.
